(19) United States
(12) Patent Application Publication
(10) Pub. No.: US 2025/0003818 A1
(43) Pub. Date: Jan. 2, 2025

(54) PRESSURE DETECTION SYSTEM FOR ELECTRIC WIRE

(71) Applicants: AUTONETWORKS TECHNOLOGIES, LTD., Yokkaichi-shi, Mie (JP); SUMITOMO WIRING SYSTEMS, LTD., Yokkaichi-shi, Mie (JP); SUMITOMO ELECTRIC INDUSTRIES, LTD., Osaka-shi, Osaka (JP)

(72) Inventors: Hirokazu KOMORI, Yokkaichi-shi (JP); Fujio SONODA, Osaka-shi (JP); Takumi OOSHIMA, Kanuma-shi (JP)

(73) Assignees: AUTONETWORKS TECHNOLOGIES, LTD., Yokkaichi-shi, Mie (JP); SUMITOMO WIRING SYSTEMS, LTD., Yokkaichi-shi, Mie (JP); SUMITOMO ELECTRIC INDUSTRIES, LTD., Osaka-shi, Osaka (JP)

(21) Appl. No.: 18/692,969

(22) PCT Filed: Nov. 26, 2021
(86) PCT No.: PCT/JP2021/043345

§ 371 Date: Mar. 18, 2024

(30) Foreign Application Priority Data
Oct. 6, 2021 (WO) PCT/JP2021/036963

(51) Int. Cl. G01L 5/10; G01L 1/12; G01L 1/20; H01B 7/00

(52) U.S. Cl. CPC G01L 5/10; G01L 1/12; G01L 1/20; H01B 7/0045

(57) ABSTRACT

A pressure detection system for electric wire that can continuously monitor application of pressure to an electric wire. A pressure detection system for an electric wire includes: a sensor unit including a tape-shaped substrate made of an elastic dielectric material, and conductive coating layers provided on both surfaces of the substrate; a detection unit configured to measure characteristic impedance between the two coating layers constituting the sensor unit; and a recording unit configured to record a history of a change in the characteristic impedance measured by the detection unit, wherein the sensor unit is disposed on an outer periphery of an electric wire in such a manner that one of the coating layers extends along a surface of the electric wire.

### TECHNICAL FIELD

The present disclosure relates to a pressure detection system for an electric wire.

### BACKGROUND ART

Electric wires are installed and routed in various types of electrical and electronic devices, transportation devices, buildings, public facilities, and the like. Damage to an electric wire may occur due to deformation of the electric wire, such as bending, or application of physical stimuli such as contact with an object around the electric wire. It is desirable to detect the occurrence of damage as early and sensitively as possible in order to avoid the case where the performance of the electric wire is seriously influenced by the damage. As a method for detecting damage in an electric wire, Patent Literature 1 discloses, for example, a cable diagnostic device including a setting means for setting a propagation speed for a pulse electrical signal for each of a plurality of sections in a cable path to be diagnosed, and an estimating means for estimating the location of a defective point in the cable path based on a measurement result of reflection characteristics of the pulse electrical signal transmitted in the cable path and the propagation speed set for each section.

### CITATION LIST

### Patent Literature

PTL1: JP 2007-333468A
PTL2: JP 2018-056287A

### SUMMARY OF INVENTION

### Technical Problem

Focusing on a characteristic that changes when an electric wire is damaged, such as the reflection characteristics of the pulse electrical signal used in the cable diagnostic device disclosed in Patent Literature 1, and detecting a change in the characteristic makes it possible to detect the occurrence of damage early based on the change. However, damage to an electric wire includes damage that occurs or progresses rapidly, and damage that occurs as a result of small loads being applied to the electric wire many times and accumulated in the electric wire. For example, pressure is applied to an electric wire when the electric wire is bent or comes into contact with another member, for example. Even if the electric wire is not damaged when such pressure is applied to the electric wire once, if the application of pressure is repeated many times, loads may accumulate in a constituent material of the electric wire, leading to the occurrence of damage such as breakage of a conductor of the electric wire. If such accumulation of loads as a result of application of pressure to an electric wire can be continuously monitored, it is possible to notice a sign of the occurrence of damage early.

In view of the above, it is an object of the present invention to provide a pressure detection system for electric wire that can continuously monitor application of pressure to an electric wire.

### Solution to Problem

A pressure detection system for electric wire according to the present disclosure includes: a sensor unit comprising a tape-shaped substrate made of an elastic dielectric material, and conductive coating layers provided on both surfaces of the substrate; a detection unit configured to measure characteristic impedance between the two coating layers constituting the sensor unit; and a recording unit configured to record a history of a change in the characteristic impedance measured by the detection unit, wherein the sensor unit is disposed on an outer periphery of the electric wire in such a manner that one of the coating layers extends along a surface of the electric wire.

### Advantageous Effects of Invention

A pressure detection system for electric wire according to the present disclosure can continuously monitor application of pressure to an electric wire.

### BRIEF DESCRIPTION OF DRAWINGS

FIG. 1 is a schematic view showing the configuration of a pressure detection system for electric wire according to an embodiment of the present disclosure.

FIGS. 2A and 2B show a cross section of a sensor tape that constitutes the pressure detection system for the electric wire. FIG. 2A shows a state where pressure is not applied, and FIG. 2B shows a state where pressure is applied.

FIG. 3 is a perspective view showing a state where the sensor tape is provided on the electric wire.

FIG. 4 is a schematic view showing an example in which the pressure detection system for the electric wire according to an embodiment of the present disclosure is provided on the electric wire whose bending angle is restricted.

### DESCRIPTION OF EMBODIMENTS

### Description of Embodiments of the Present Disclosure

First, embodiments of the present disclosure will be described.

A pressure detection system for electric wire according to the present disclosure includes: a sensor unit comprising a tape-shaped substrate made of an elastic dielectric material, and conductive coating layers provided on both surfaces of the substrate; a detection unit configured to measure characteristic impedance between the two coating layers constituting the sensor unit; and a recording unit configured to record a history of a change in the characteristic impedance measured by the detection unit, wherein the sensor unit is disposed on an outer periphery of the electric wire in such a manner that one of the coating layers extends along a surface of the electric wire.

In the pressure detection system for the electric wire, the sensor unit, which comprises the conductive coating layers provided on both surfaces of the substrate made of an elastic dielectric material, is disposed on the outer periphery of the electric wire. When pressure is applied to the electric wire from a side thereof as a result of the electric wire being bent, for example, the dielectric material is compressed in the thickness direction, and the sensor unit deforms in such a manner that the distance between the two coating layers decreases. As a result of the deformation of the sensor unit, the characteristic impedance between the two coating layers changes. By detecting the change in the characteristic impedance with use of the detection unit, it is possible to detect application of pressure to the electric wire. Since the substrate of the sensor unit is made of an elastic material, when the applied pressure is removed as a result of bending of the electric wire being canceled, for example, the deformation of the sensor unit is also canceled, and the distance between the two coating layers returns to its original state or a state close to the original state, and the characteristic impedance also returns to its original value or a value close to the original value. However, a history indicating that the characteristic impedance temporarily changed is recorded in the recording unit.

When the change in the characteristic impedance is continuously detected by the detection unit and the history of the change in the characteristic impedance is continuously recorded in the recording unit for a certain period of time, it is possible to obtain information regarding a history of pressure application to the electric wire from the history of the change in the characteristic impedance recorded in the recording unit. Thus, it is possible to continuously monitor application of pressure to the electric wire based on the history recorded in the recording unit. Also, information regarding the history of pressure application to the electric wire can be used as information indicating accumulation of loads in the electric wire or a sign of the occurrence of damage.

Here, it is preferable that the sensor unit is spirally wound around the outer periphery of the electric wire. In this case, the sensor unit can be stably held on the outer periphery of the electric wire, and even when pressure is applied to the electric wire from different directions as a result of bending or the like, the sensor unit can detect application of pressure from different directions with the same level of sensitivity.

It is preferable that, defining that the amount of the change in the characteristic impedance or an amount obtained by converting the amount of the change to a deformation amount of the sensor unit or the electric wire as an index amount, the recording unit records, as the history, at least one selected from the group consisting of: an integrated value of the index amount; the number of times the index amount exceeded a criterion value or the number of times the index amount exceeded respective criterion values; and a sum of weighted numbers which are obtained by weighting of the numbers of times the index amount exceeded respective criterion values depending on the ranges divided by the criterion values. In this case, it is possible to monitor the history of pressure application to the electric wire from various viewpoints by selecting the manner of recording the index amount in the recording unit. The integrated value of the index amount reflects the amount of loads accumulated in the electric wire as a result of application of pressure. The numbers of times the index amount exceeded respective criterion values each indicate the number of times a load larger than a predetermined value was applied. The sum of weighted numbers which are obtained by weighting of the numbers of times depending on the ranges divided by the criterion values corresponds to a value obtained by counting the number of times loads were applied, taking the amount of each load into account.

It is preferable that the substrate is made of a rubber. In this case, the sensor unit has high durability, and can continuously monitor pressure application to the electric wire for a long period of time. It is preferable that the substrate is made of a rubber having a high dielectric constant.

It is preferable that the detection unit further measures inductance of the coating layers. When a large impact is applied to the electric wire, the coating layers of the sensor unit may be stretched in a direction along their surfaces, and may become thinner. In this case, the inductance of the coating layers changes. Accordingly, by measuring the inductance of the coating layers with use of the detection unit, it is possible to detect sudden application of impact in addition to continuous application of pressure to the electric wire.

It is preferable that the detection unit further detects resistance of the coating layers. When a very large impact is applied to the electric wire, the coating layers of the sensor unit may break. In this case, the resistance of the coating layers changes. Accordingly, by measuring the resistance of the coating layers with use of the detection unit, it is possible to detect sudden application of large impact in addition to continuous application of pressure to the electric wire.

It is preferable that the electric wire constitutes a wire harness for an automobile. Pressure is likely to be applied to a wire harness installed in an automobile due to vibration of the vehicle, movement of constituent members, or contact with surrounding members, for example. Therefore, by providing the pressure detection system for electric wire according to an embodiment of the present disclosure on a wire harness for an automobile and continuously monitoring application of pressure, it is possible to be aware of the state of accumulation of loads as a result of application of pressure to the wire harness, and take measures such as replacement of the wire harness before significant damage occurs.

It is also preferable that the electric wire constitutes a composite wire for an electric brake of an automobile. A composite wire for an electric brake of an automobile is likely to be bent. When a history of bending of the electric wire is monitored, it is possible to be aware of accumulation of loads as a result of the electric wire being excessively bent or bent in an unexpected direction, and prevent a serious influence on the operation of the electric brake by replacing the electric wire, for example,

### Details of Embodiments of the Present Disclosure

A pressure detection system for electric wire according to an embodiment of the present disclosure will be described below in detail with reference to the drawings. In the specification, terms used to indicate the shapes and the arrangement of various components, such as straight and spiral, include not only geometrically strict concepts, but also error within the range allowed in an electric wire.

### <Configuration of Pressure Detection System for Electric Wire>

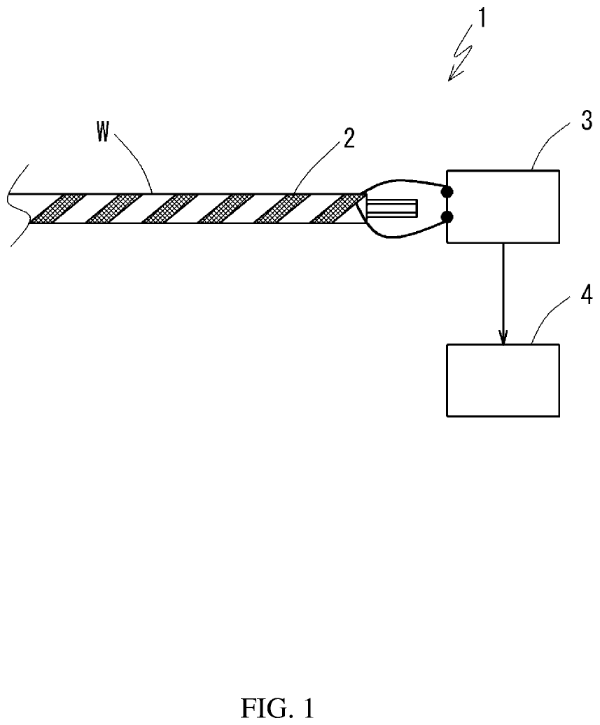

FIG. 1 schematically shows the configuration of a pressure detection system 1 for an electric wire according to an embodiment of the present disclosure. The pressure detection system 1 for an electric wire according to the present embodiment is attached to an electric wire W and detects application of pressure to the electric wire W. The pressure detection system 1 for an electric wire is installed together with the electric wire W in a device, such as an automobile, in which the electric wire W is installed.

The pressure detection system 1 for an electric wire includes a sensor unit 2, a detection unit 3, and a recording unit 4. The sensor unit 2 is attached to the electric wire W, and application of pressure to the electric wire W is reflected in deformation of the sensor unit 2. The deformation of the sensor unit 2 is detected by the detection unit 3. A history of detection results obtained by the detection unit 3 is recorded in the recording unit 4.

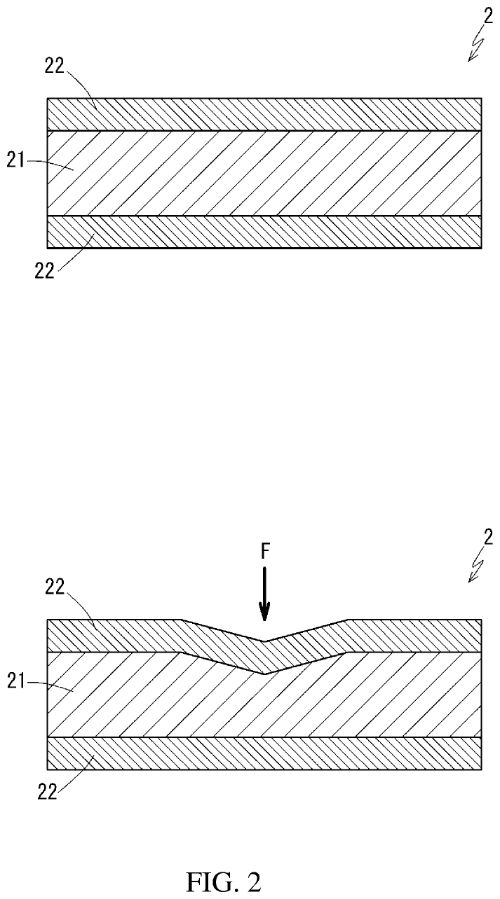

The sensor unit 2 is configured as a sensor tape, and includes a tape-shaped substrate 21 made of an elastic dielectric material, and conductive coating layers 22 and 22 provided on both surfaces of the substrate 21 as shown in a cross-sectional view of FIG. 2A. The coating layers 22 and 22 provided on both surfaces of the substrate 21 are insulated from each other. There is no particular limitation on specific materials of the substrate 21 and the coating layers 22 and 22, but the substrate 21 is preferably made of a rubber, and the coating layers 22 and 22 are preferably made of a metal material such as copper or a copper alloy. The coating layers 22 and 22 are fixed to the surfaces of the substrate 21 through bonding or vapor deposition or plating of the metal material, for example. An adhesive layer or a pressure-sensitive adhesive layer (not shown) for fixing the sensor tape 2 to the electric wire W may be provided as needed on the surface of one coating layer 22. There is no particular limitation on the specific shape of the sensor tape 2 as long as the sensor tape is a tape-shaped sensor. Note that “tape-shaped” means that the sensor tape is an elongated sheet whose length is larger than its thickness and width.

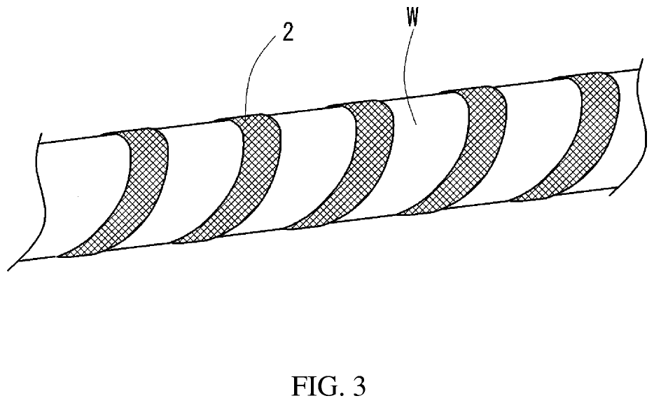

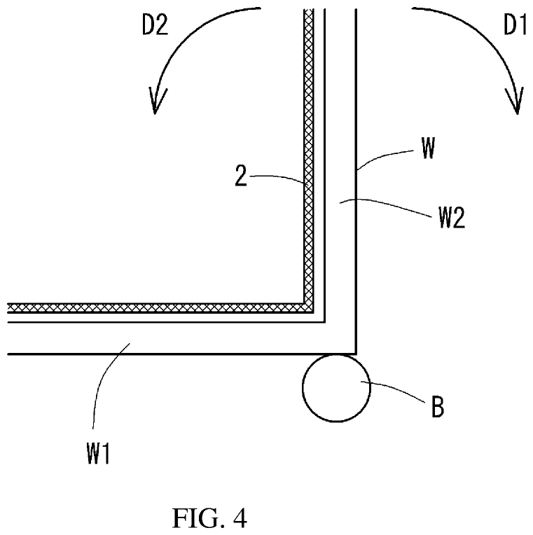

FIGS. 1 and 3 show a state where the sensor tape 2 is installed on the electric wire W. The sensor tape 2 is disposed on the outer periphery of the electric wire W with one of the two coating layers 22 and 22 extending along a surface of the electric wire W. The sensor tape 2 can be disposed in a suitable manner as long as the surface of one coating layer 22 extends along the surface of the electric wire W. For example, the sensor tape 2 may be disposed straight (linearly) so that the longitudinal direction of the sensor tape 2 extends along an axial direction of the electric wire W, or may be spirally wound around the outer periphery of the electric wire W as shown in FIG. 3. The configuration in which the sensor tape 2 is spirally wound is advantageous in that the sensor tape 2 can be stably held on the outer periphery of the electric wire W and it is possible to detect application of pressure irrespective of the direction in which the pressure is applied. The configuration in which the sensor tape 2 extends along the axial direction of the electric wire W is advantageous in that it is possible to sensitively detect application of pressure in a specific direction as in a configuration described later with reference to FIG. 4. In the case where the sensor tape 2 is spirally wound, spaces may be provided between turns of the spiral as shown in FIG. 3, or the sensor tape 2 may be wound densely without spaces being provided between the turns. In the case where the sensor tape 2 is wound without spaces being provided between the turns, it is possible to secure insulation of the coating layers 22 between the turns by fixing the sensor tape 2 to the electric wire W with an adhesive layer or a pressure-sensitive adhesive layer provided on the sensor tape 2 as appropriate. The sensor tape 2 disposed on the outer periphery of the electric wire W may be exposed to the external environment, or another layer such as a sheath layer may be further provided on an outer periphery of the assembly obtained by disposing the sensor tape 2 on the outer periphery of the electric wire W. The sensor tape 2 may be provided along the longitudinal direction of the electric wire W in a portion of the electric wire W or over the entire electric wire W.

There is no particular limitation on the structure and type of electric wire W on which the sensor tape 2 is installed. The sensor tape 2 may be disposed on a single insulated wire or a wire harness including a plurality of insulated wires. In the case where the sensor tape 2 is disposed on a wire harness, the sensor tape 2 may be disposed on an outer periphery of one or more insulated wires constituting the wire harness, but it is preferable to dispose the sensor tape 2 on the outer periphery of the entire wire harness from the viewpoint of monitoring application of pressure to the entire wire harness.

The detection unit 3 is a measuring device that measures characteristic impedance between the two coating layers 22 and 22 constituting the sensor tape 2. The characteristic impedance is measured by inputting an electrical signal that includes an AC component to the coating layers 22 and 22 and measuring the characteristic impedance of a response signal. The characteristic impedance may be measured using a transmission method, or may be measured using a reflection method, but it is preferable to use the reflection method because the measurement can be performed by connecting the detection unit 3 to an end of the sensor tape 2. Furthermore, it is preferable that the detection unit 3 measures the characteristic impedance using a time domain method or a frequency domain method. The detection unit 3 may be capable of measuring electrical characteristics other than the characteristic impedance, with respect to the coating layers 22 and 22. Examples of characteristics that are preferably measured in addition to the characteristic impedance include inductance and resistance.

The recording unit 4 is configured as a storage device, for example, and measurement results of the characteristic impedance between the coating layers 22 and 22 constituting the sensor tape 2 are input to the recording unit 4 by the detection unit 3. The recording unit 4 records a history of a change in the characteristic impedance. Here, the history of the change in the characteristic impedance is information indicating how the characteristic impedance changed in a predetermined period of time. Specific information recorded as the history will be described later in detail. For example, the number of times the characteristic impedance changed by an amount exceeding a predetermined criterion value is recorded as the history.

In the pressure detection system 1 for an electric wire, the detection unit 3 continuously measures the characteristic impedance, and the recording unit 4 continuously records the history. Preferably, the characteristic impedance is constantly measured and the history is constantly recorded while the device, such as an automobile, in which the electric wire W is installed is operating. After a predetermined period has elapsed, the recording unit 4 outputs the recorded history in such a manner that an administrator or the like of the device can recognize the history. For example, the history is output so that an automobile mechanic can check the history when inspecting the automobile. Alternatively, in the middle of the period for which the history is recorded, the recording unit 4 outputs the history recorded by that time. For example, a currently recorded history is displayed continuously or intermittently in an instrument panel of the automobile so that the driver can view the history.

### <Detection of Pressure Applied to Electric Wire by Sensor Unit>

The following considers a case where pressure is applied to the electric wire W provided with the sensor tape 2 on the outer periphery as shown in FIGS. 1 and 3. Here, pressure applied to the electric wire W is a force applied in such a manner as to press the electric wire W from a side of the electric wire W, and examples thereof include pressure applied from the outside of the electric wire W when the electric wire W comes into contact with another object or impact is applied to the electric wire W, and pressure applied to the electric wire W as a result of the electric wire W being bent.

When pressure is applied to the electric wire W, the sensor tape 2 disposed on the outer periphery of the electric wire W is also subjected to the pressure. That is, the sensor tape 2 is subjected to pressure that compresses the sensor tape 2 in a thickness direction. Since the substrate 21 of the sensor tape 2 is made of an elastic material, when the sensor tape 2 is subjected to pressure F as shown in FIG. 2B, the substrate 21 is compressed and elastically deforms, and the thickness is reduced in a localized region. At this time, at least one of the coating layers 22 and 22 fixed to the surfaces of the substrate 21 is displaced as the substrate 21 is compressed, and the distance between the two coating layers 22 and 22 decreases. As a result, the characteristic impedance between the two coating layers 22 and 22 detected by the detection unit 3 changes. In a case where the sensor tape 2 can be considered as being disposed along a simple flat surface, the characteristic impedance decreases as a result of an increase in a capacitance component. The larger the pressure applied to the electric wire W is and the larger the deformation of the sensor tape 2 is, the larger the amount of change in the characteristic impedance becomes. When a change in the characteristic impedance between the coating layers 22 and 22 of the sensor tape 2 is detected by the detection unit 3 as described above, a record of the change is recorded in the recording unit 4.

When pressure that has been applied to the electric wire W is removed as a result of bending of the electric wire W being canceled, for example, and the pressure F that has been applied to the sensor tape 2 is removed, the thickness of the substrate 21 returns to its original state (or a state close to the original state, the same applies to the following description regarding restoration to the original state) due to resilience of the elastic substrate 21. The two coating layers 22 and 22 also return to their original positional relationship. Accordingly, the characteristic impedance between the coating layers 22 and 22 also returns to its original value. Under a situation in which application of pressure to the electric wire W and removal of the pressure are repeated, the impedance between the two coating layers 22 and 22 of the sensor tape 2 repeatedly changes and returns to the state before the change along with the elastic deformation of the substrate 21 and restoration of the substrate 21. While such repetition continues, a history of a change in the characteristic impedance is recorded and accumulated in the recording unit 4. As described above, by disposing the sensor tape 2, which includes the conductive coating layers 22 and 22 provided on both surfaces of the substrate 21 made of an elastic dielectric material, on the outer periphery of the electric wire W, it is possible to detect application of pressure to the electric wire W as a change in the characteristic impedance between the coating layers 22 and 22, using reversible compressive deformation of the elastic substrate 21, and record the application of pressure every time pressure is applied under a situation in which pressure is repeatedly applied to the electric wire W.

As described above, the material of the substrate 21 is not particularly limited as long as the material is an elastic dielectric material, and it is possible to preferably use various foamed resins, elastomers, and rubber, for example. However, from the viewpoint of continuously detecting application of pressure with use of the sensor tape 2 with high sensitivity for a long period of time, the substrate 21 is preferably made of a material that elastically deforms and restores its original shape by sensitively responding to application and removal of pressure, and has high durability. From this viewpoint, it is preferable that the substrate 21 is made of a rubber. There is no particular limitation on the type of rubber, and it is possible to preferably use silicone rubber, chloroprene rubber, nitrile rubber, and the like. From the viewpoint of suppressing deterioration due to the surrounding environment and maintaining high durability, use of rubber that is easily hydrolyzed, such as polyester-based urethane rubber, should be avoided. Also, it is preferable that the substrate 21 has a high dielectric constant. This is because, the higher the dielectric constant of the substrate 21 is, the larger the amount of change in the characteristic impedance relative to a deformation amount of the substrate 21 becomes, and the more sensitively application of pressure to the electric wire W can be detected. The dielectric constant of the substrate 21 can be effectively increased by adding an inorganic filler made of a ferroelectric substance such as barium titanate to an organic elastic material such as rubber.

In a case where the position on the electric wire W to which pressure is applied due to bending or the like may change in the longitudinal direction of the electric wire W, it is possible to identify the position to which pressure was applied by using the time domain method or the frequency domain method in the measurement of the characteristic impedance performed by the detection unit 3. In the case of the time domain method, it is possible to identify the position to which pressure was applied by inputting a pulse electrical signal to the coating layers 22 and 22 and converting the time at which the characteristic impedance changed to a position in the axial direction of the electric wire W. In the case of the frequency domain method, an electrical signal including a plurality of frequency components is input to the coating layers 22 and 22, and Fourier transform is performed on a response signal to convert frequency information to information indicating a position on the electric wire W. Information obtained using these methods and indicating the position to which pressure was applied can also be stored in the recording unit 4.

### <Recording of History by Recording Unit and Monitoring of Pressure Application>

As described above, when the sensor tape 2 deforms as a result of pressure being applied to the electric wire W, the characteristic impedance between the two coating layers 22 and 22 changes, but the change in the characteristic impedance is canceled when the pressure is removed. However, a history indicating that the characteristic impedance temporarily changed is recorded and accumulated in the recording unit 4. In many cases, pressure temporarily applied to the electric wire W as a result of bending of the electric wire W or the like dose not immediately cause damage to the electric wire W, but may be accumulated as a load in the electric wire W. Accordingly, when application of pressure is repeated many times, the electric wire W is damaged or deteriorates over time. For example, the repeated application of pressure may cause breakage of a conductor constituting the electric wire W.

In the pressure detection system 1 for an electric wire according to the present embodiment, it is possible to obtain information indicating a history of pressure application to the electric wire W from a history regarding deformation of the sensor tape 2 that is detected based on a change in the characteristic impedance between the coating layers 22 and 22 and accumulated as information in the recording unit 4. Based on the information indicating the history, it is possible to continuously monitor application of loads to the electric wire W. When pressure is applied to the electric wire W as a result of bending or the like, a load is applied to the electric wire W, but if the load is small, the load does not cause a detectable irreversible change in the electric wire W itself or the sensor tape 2. Accordingly, even when an inspection such as measurement of electrical characteristics is performed on the electric wire W or the sensor tape 2 that has been used for a predetermined period of time in an environment in which pressure may be applied, it is difficult to determine whether or not a load was applied in the past or determine the magnitude of a load that was applied. However, the pressure detection system 1 for an electric wire according to the present embodiment makes it possible to monitor application of loads over time by recording application of loads every time a load originating from pressure is applied to the electric wire W. For example, in a case where information included in the history accumulated in the recording unit 4 indicates that pressure has been applied to the electric wire W more than a predetermined number of times or the magnitude of pressure that has been applied to the electric wire W exceeds a predetermined criterion value, it can be considered that loads equal to or more than a criterion amount have accumulated in the electric wire W, and there is a sign of the occurrence of damage to the electric wire W. Accordingly, it is possible to consider taking measures such as maintenance or replacement of the electric wire W to deal with the accumulated loads. Thus, it is possible to avoid a situation in which irreversible damage to the electric wire W, such as breakage of the conductor of the electric wire due to metal fatigue, occurs as a result of loads being accumulated through application of pressure, and to take measures in a timely manner.

When recording the history of the change in the characteristic impedance in the recording unit 4, there is no particular limitation on the content of the history. The content of the history can be suitably determined in accordance with information that is to be obtained based on the history. An index amount that is recorded in the history as the index of pressure application may be the amount of change in the characteristic impedance between the coating layers 22 and 22 or an amount obtained by converting the amount of change in the characteristic impedance to a deformation amount of the sensor tape 2 or the electric wire W. Here, the “deformation amount of the sensor tape 2 or the electric wire W” is an amount indicating the magnitude of deformation that occurred in the sensor tape 2 or the electric wire W, and examples thereof include an amount of dimensional change caused by pressure application (a compression amount of the substrate 21 or the magnitude of compressive deformation of the electric wire W), a bending angle, and a bending curvature. The larger the amount of dimensional change is, or the larger the bending angle is, i.e., the larger the change in the angle caused by bending is, or the larger the bending curvature is (i.e., the smaller the radius of curvature is), the larger the pressure applied to the electric wire W is. In the case where the detection unit 3 also obtains information indicating the position at which the electric wire W was bent, it is preferable to record the information in the recording unit 4.

The above-described index amount, i.e., the amount of change in the characteristic impedance, or an amount obtained by converting the amount of change to a deformation amount of the sensor tape 2 or the electric wire W may be recorded as is in the recording unit 4, or may be recorded as a statistical value obtained by performing predetermined statistical processing. In the case where the index amount is recorded as it is, it is conceivable to accumulate values of the index amount exceeding a predetermined threshold. In this case, many values of the index amount are recorded in time series in the recording unit 4. It is also possible to record, together with each value of the index amount, information indicating a point in time at which the value was obtained. In this case, it is possible to obtain detailed information regarding the history of pressure application to the electric wire W, but the amount of data recorded in the recording unit 4 is large, and it is difficult for the administrator or the like of the device in which the electric wire W is installed to easily and clearly recognize information regarding the pressure applied to the electric wire W, and appropriately use the information to take measures such as maintenance or replacement of the electric wire W. Therefore, as a method for recording information of the history regarding the electric wire W in a simple and clear form, it is preferable to adopt a configuration in which the index amount is recorded as a statistical value.

The statistical value is obtained by processing the index amount in accordance with predetermined criteria. Statistical processing can be performed on the index amount in such a manner that the larger the amount of loads accumulated in the electric wire W as a result of pressure application is, the larger the statistical value becomes. Examples of statistical values to be recorded in the recording unit 4 include:
(i) an integrated value of the index amount;
(ii) the number of times the index amount exceeded a criterion value, or the numbers of times the index amount exceeded respective criterion values; and
(iii) a sum of weighted numbers which are obtained by weighting of the numbers of times the index amount exceeded respective criterion values depending on the ranges divided by the criterion values.

In the case of (i) described above, values of the index amount are simply accumulated for a predetermined period of time. For example, when the index amount is the bending angle of the electric wire W, values of the bending angle are added up over time, such as 90°+150°+120°+ . . . . In this case, it is possible to adopt a configuration in which all values of the index amount that have been obtained are added up at predetermined time intervals, or a configuration in which a threshold is set for the index amount, and only values of the index amount exceeding the threshold are added up. The total amount of loads applied to the electric wire W as a result of pressure application is reflected well in the statistical value (i).

In the case of (ii) described above, the number of times the index amount exceeded a predetermined criterion value is counted. For example, when the index amount is the bending angle of the electric wire W and the criterion value is 90°, the number of times the electric wire W was bent by an angle larger than 90° is counted. In the case where a plurality of criterion values are set, the number of times the index amount was more than Tᵢ and Tᵢ₊₁ or less is counted for each criterion value Tᵢ, where Tᵢ represents the i-th criterion value as counted in the ascending order (note that, for the largest criterion value, the number of times the index amount was more than the criterion value is counted). For example, when the index amount is the bending angle of the electric wire W and the three criterion values 90°, 120°, and 150° are set, the number of times the bending angle of the electric wire W was more than 90° and 120° or less, the number of times the bending angle was more than 120° and 150° or less, and the number of times the bending angle was more than 150° are independently counted. If pressure applied to the electric wire W as a result of bending or the like is small, the pressure is not substantially accumulated as a load. However, when the applied pressure exceeds a certain level and the amplitude of stress applied to the material of the electric wire W is large, a load is accumulated as fatigue in the material, and repeated application of such pressure may lead to irreversible damage to the electric wire W. Therefore, by setting a threshold for the index amount and counting the number of times the index amount exceeded the threshold, it is possible to selectively monitor application of pressure that may impose a load on the material of the electric wire W.

In the case of (iii) described above, the number of times the index amount exceeded each of the predetermined criterion values is weighted according to the value of the index amount, rather than simply counting the number of times the index amount exceeded the criterion value. That is, a plurality of criterion values are set for the index amount, and weighting coefficients are set for respective ranges divided by the criterion values in such a manner that the larger the value of the index amount is, the larger the weighting coefficient is. With respect to each range, the number of times the index amount within that range was obtained is multiplied by the weighting coefficient corresponding to that range, and values obtained in this manner for all ranges are added up. When the number of criterion values set for the index amount is n, the i-th criterion value as counted in the ascending order is represented by Tᵢ, the weighting coefficient of a range in which the index amount is more than Tᵢ and Tᵢ₊₁ or less is represented by Ki, and the number of times the index amount within this range was observed is represented by xᵢ (note that, when i=n, the number of times the index amount exceeded the criterion value Tₙ is represented by xₙ). In this case, the following statistical value is obtained.

$${\sum }_{i = 1}^{n} {K}_{i} {x}_{i}$$

For example, assume that the index amount is the bending angle of the electric wire W, the three criterion values 90°, 120°, and 150° are set, the weighting coefficient is 1 for a range in which the bending angle is more than 90° and 120° or less, the weighting coefficient is 2 for a range in which the bending angle is more than 120° and 150° or less, and the weighting coefficient is 3 for a range in which the bending angle is more than 150°. In this case, if a bending angle more than 90° and 120° or less was observed five times, a bending angle more than 120° and 150° or less was observed three times, and a bending angle more than 150° was observed once, the statistical value 1×5+2×3+3×1=14 is obtained. When pressure is applied to the electric wire W as a result of bending or the like, the larger the amplitude of stress applied to the material of the electric wire W is, the larger the load accumulated in the material is, even if the number of times such pressure was applied is small. Therefore, the statistical value (iii) can be used as an index for evaluating the degree of accumulated loads by giving consideration to both the amplitude of stress and the number of times a load was applied.

As described above, the statistical values (i) to (iii) are used to monitor application of loads as a result of bending of the electric wire W from different viewpoints, and it is preferable to record at least one of these statistical values in the recording unit 4 in accordance with the desired manner of monitoring. It is possible to select the index amount, the type of statistical value, and criterion values and coefficients used to calculate the statistical value in accordance with the type of electric wire W, characteristics of the electric wire W, the environment in which the electric wire W is installed, and the like so that the electric wire W can be monitored from a desired viewpoint. It is also preferable to use a plurality of statistical values. In the case where the electric wire W may be bent at a plurality of positions, the time domain method or the frequency domain method may be used in the measurement of the characteristic impedance performed by the detection unit 3 to obtain statistical values for respective positions on the electric wire W, and the obtained values may be stored in the recording unit 4. The administrator or the like of the device in which the electric wire W is installed can determine that the larger the statistical value is, the larger the loads accumulated in the electric wire W as a result of pressure application is, and can use the statistical value as an index for measures such as maintenance or replacement of the electric wire W.

### <Specific Example of Monitoring of Bending of Electric Wire>

Here, the following describes a case where the pressure detection system 1 for an electric wire is applied to an electric wire W whose bending angle is restricted, as an example of a case where application of pressure to the electric wire W is monitored with use of the pressure detection system 1 for an electric wire according to the embodiment of the present disclosure. As shown in FIG. 4, an intermediate portion of the electric wire W is fixed to a bracket B. A region of the electric wire W on one side of the portion fixed to the bracket B is a fixed portion W1 that does not move, and a region of the electric wire W on the other side of the portion fixed to the bracket B is a movable portion W2 that is supported in such a manner as to be pivotable about the portion fixed to the bracket B. In an initial state, the movable portion W2 is bent by 90° with respect to the fixed portion W1, and the movable portion W2 is allowed to be bent in a direction away from the fixed portion W1 (allowable bending direction D1) from the position in the initial state. However, even if the movable portion W2 is bent in the allowable bending direction D1, it is not preferable to bend the movable portion W2 by more than 90°, and a limit is set for the number of times the movable portion W2 is allowed to be bent by more than 90°. Also, it is not preferable to bend the movable portion W2 in a direction toward the fixed portion W1 (bending restricted direction D2), and a limit is set for the number of times the movable portion W2 is allowed to be bent in this direction D2.

In the initial state shown in FIG. 4 in which the movable portion W2 is raised by being bent by 90° with respect to the fixed portion W1, the sensor tape 2 is disposed on the outer periphery of the electric wire W including the portion fixed to the bracket B. At this time, the sensor tape 2 may be spirally wound around the electric wire W, but the configuration in which the sensor tape 2 is disposed along the axial direction of the electric wire W on a surface of the electric wire W in the direction in which the electric wire W is not intended to be bent is more advantageous in order to sensitively detect bending of the electric wire W in the direction in which the electric wire W is not intended to be bent. In this case, it is preferable to dispose the sensor tape 2 on the left side of the electric wire W corresponding to the bending restricted direction D2.

In the initial state, the electric wire W has already been bent in its portion fixed to the bracket B, and accordingly, the sensor tape 2 has been deformed to some extent. When the electric wire W is bent in the bending restricted direction D2 from this state, the sensor tape 2 is further deformed and the measured value of the characteristic impedance decreases. The amount of change in the characteristic impedance (or a deformation amount of the sensor tape 2 or the electric wire W corresponding to the amount of change in the characteristic impedance, the same applies to the following description) is recorded as a record in accordance with any of the rules described above in (i) to (iii) in the recording unit 4.

On the other hand, when the electric wire W is bent in the allowable bending direction D1 from the initial state, the deformation of the sensor tape 2 in the initial state is canceled until the electric wire W is bent by 90° (until the electric wire W extends straight along the fixed portion W1), and therefore, substantial reduction in the measured value of the characteristic impedance does not occur. Therefore, bending of the electric wire W in the allowable bending direction D1 by an angle equal to or less than 90° is not recorded in the recording unit 4. However, when the electric wire W is bent in the allowable bending direction D1 by an angle more than 90°, the amount of deformation of the sensor tape 2 increases again. Accordingly, the characteristic impedance decreases. The amount of change in the characteristic impedance is recorded in accordance with any of the rules described above in (i) to (iii) in the recording unit 4.

As described above, when the electric wire W is bent in the bending restricted direction D2 or is bent in the allowable bending direction D1 by an angle more than 90°, a record of the bending is recorded in the recording unit 4 as a change in the characteristic impedance between the coating layers 22 and 22 caused by deformation of the sensor tape 2 as a result of pressure application. When the thus recorded history of bending has exceeded a predetermined allowable level, i.e., exceeded a predetermined allowable number of times of bending, a notification is given as appropriate to the administrator or the like of the device in which the electric wire W is installed, via an alarm device to urge the administrator or the like to perform maintenance or replacement of the electric wire W. A plurality of thresholds may be set as appropriate when recording the history in the recording unit 4. For example, it is conceivable to distinguish between a case where the electric wire W is bent in the allowable bending direction D1 by an angle more than 90° and 100° or less and a case where the electric wire W is bent in the allowable bending direction D1 by an angle more than 100°, and independently count the numbers of times of the respective types of bending as described above in (ii), or add the numbers of times of the respective types of bending as described above in (iii) by applying a larger weighting coefficient to the latter type of bending.

An example of such an electric wire W whose bending direction and bending angle are restricted is a composite wire for an electric brake of an automobile. A composite wire for an electric brake includes a core wire obtained by twisting together a plurality of insulated wires including a power line and a communication line, and the sensor tape 2 is disposed on an outer periphery of the core wire. A wire wrapping tape is disposed on the outer periphery of the sensor tape 2 as necessary and then a sheath is formed thereon. Some electric wires and wire harnesses for an automobile are likely to be bent due to vibration of the vehicle, movement of constituent members, contact with other members, or the like, and when loads are accumulated in those electric wires and wire harnesses as a result of pressure application and the electric wires and the wire harnesses are damaged, the damage may have a significant influence on the functions of the automobile. Therefore, it is desirable to continuously monitor pressure application to those electric wires and wire harnesses. A composite wire for an electric brake is also likely to be bent due to vibration or the like because it is disposed in the suspension of an automobile. When loads accumulate in the composite wire as a result of bending for a long period of time, the accumulated loads may have a significant influence, for example, may cause breakage of a conductor. Therefore, it is desirable to continuously monitor a history of bending to appropriately prevent the influence of accumulation of loads.

### <Detection of Irreversible Damage>

In the cases described above, a history of pressure application to the electric wire W as a result of bending of the electric wire W or the like is detected based on reversible deformation of the sensor tape 2. Pressure that causes such reversible deformation of the sensor tape 2 is unlikely to immediately cause damage to the electric wire W, and accumulation of loads over time is monitored by recording the history of pressure application. However, when a large impact is applied to the electric wire W, irreversible deformation of the electric wire W may occur and the electric wire W may be damaged. The pressure detection system 1 for an electric wire according to the present embodiment can be used for detection of such an irreversible change in the electric wire W, as well as monitoring of accumulation of loads due to pressure.

When a large impact is temporarily applied to the electric wire W as a result of the electric wire W being bent extremely or colliding with another object, for example, irreversible damage such as breakage or cracking may occur to a conductor or a coating material constituting the electric wire W. At this time, irreversible deformation such as breakage or cracking also occurs in the coating layers 22 and 22 of the sensor tape 2 disposed on the outer periphery of the electric wire W. When such damages occur, the characteristic impedance between the two coating layers 22 and 22 measured by the detection unit 3 changes. Unlike the above-described reversible change in the characteristic impedance that occurs along with elastic deformation of the substrate 21 when pressure is applied, once this change in the characteristic impedance occurs, the changed characteristic impedance is maintained. By detecting such an irreversible change in the characteristic impedance, it is possible to detect an irreversible change that occurred in the electric wire W. At this time, it is desirable to issue an alert or the like from the pressure detection system 1 for an electric wire to urge the administrator or the like of the device in which the electric wire W is installed to check the state of the electric wire W early and consider taking measures such as maintenance or replacement.

Furthermore, when the detection unit 3 is configured to be capable of measuring the inductance and the resistance in addition to the characteristic impedance between the coating layers 22 and 22, it is possible to use measurement results of these characteristics to detect an irreversible change in the coating layers 22 and 22. When a large impact is suddenly applied to the electric wire W as a result of the electric wire W being bent extremely or colliding with another object, for example, a large force may also be applied to the sensor tape 2 in such a manner as to stretch the surface of the tape. At this time, the substrate 21 made of an elastic material can be stretched by the force, and the coating layers 22 and 22 made of metal may also be stretched accompanying the stretched substrate 21. The coating layers 22 and 22 stretched in the direction along their surfaces become thinner. As a result of the coating layers 22 and 22 being stretched, the inductance of the coating layers 22 and 22 changes. Basically, the inductance increases. When the inductance between the two coating layers 22 and 22 or between at least one of the coating layers 22 and the earth potential is measured and monitored, it is possible to detect the occurrence of an irreversible change in the electric wire W based on an irreversible change in the inductance.

When a larger impact is suddenly applied to the electric wire W, a very large force is also applied to the sensor tape 2. At this time, the coating layers 22 and 22 made of metal may not be able to accompany the stretched elastic material, and may be cracked or broken. When the coating layers 22 and 22 are cracked or broken, the resistance value of the coating layers 22 and 22 changes. Basically, the resistance value increases. When the resistance value of at least one of the coating layers 22 is measured and monitored between two end portions of the sensor tape 2, it is possible to detect the occurrence of a large irreversible change in the electric wire W based on an irreversible change in the resistance value.

Although an embodiment of the present disclosure has been described in detail, the present invention is not limited to the above embodiment, and various modifications can be made within a scope not departing from the gist of the present invention.

### LIST OF CRITERION NUMERALS

1 Pressure detection system for electric wire
2 Sensor tape (sensor unit)
21 Substrate
22 Coating layer
3 Detection unit
4 Recording unit
B Bracket
D1 Allowable bending direction
D2 Bending restricted direction
F Pressure applied to sensor tape
W Electric wire
W1 Fixed portion
W2 Movable portion

1. A pressure detection system for electric wire, comprising:
a sensor unit comprising:
a tape-shaped substrate made of an elastic dielectric material, and
conductive coating layers provided on both surfaces of the substrate;
a detection unit configured to measure characteristic impedance between the two coating layers constituting the sensor unit; and
a recording unit configured to record a history of a change in the characteristic impedance measured by the detection unit,
wherein the sensor unit is disposed on an outer periphery of an electric wire in such a manner that one of the coating layers extends along a surface of the electric wire.

2. The pressure detection system for electric wire according to claim 1,
wherein the sensor unit is spirally wound around the outer periphery of the electric wire.

3. The pressure detection system for electric wire according to claim 1,
wherein, defining that the amount of the change in the characteristic impedance or an amount obtained by converting the amount of the change to a deformation amount of the sensor unit or the electric wire as an indicator quantity,
the recording unit records, as the history, at least one selected from the group consisting of:
an integrated value of the index amount;
a number of times the index amount exceeded a criterion value or numbers of times the index amount exceeded respective reference values; and
a sum of weighted numbers which are obtained by weighting of the numbers of times the index amount exceeded respective criterion values depending on the ranges divided by the criterion values.

4. The pressure detection system for electric wire according to claim 1,
wherein the substrate is made of a rubber.

5. The pressure detection system for electric wire according to claim 1,
wherein the detection unit further measures inductance of the coating layers.

6. The pressure detection system for electric wire according to claim 1,
wherein the detection unit further measures resistance of the coating layers.

7. The pressure detection system for electric wire according to claim 1,
wherein the electric wire constitutes a wire harness for an automobile.

8. The pressure detection system for electric wire according to a e claim 1,
wherein the electric wire constitutes a composite wire for an electric brake of an automobile.
